(19) United States
(12) Patent Application Publication
(10) Pub. No.: US 2025/0284157 A1
(43) Pub. Date: Sep. 11, 2025

(54) OPTICAL PATH CONTROL MEMBER AND DISPLAY DEVICE COMPRISING SAME

(71) Applicant: LG INNOTEK CO., LTD., Seoul (KR)

(72) Inventors: Jin Gyeong PARK, Seoul (KR); Byung Sook KIM, Seoul (KR); Kwang Ho PARK, Seoul (KR)

(21) Appl. No.: 18/859,408

(22) PCT Filed: Mar. 15, 2023
(86) PCT No.: PCT/KR2023/003464

§ 371 Date: Oct. 23, 2024

(30) Foreign Application Priority Data
Apr. 25, 2022 (KR) 10-2022-0051038

(51) Int. Cl. G02F 1/1335; G02F 1/13; G02F 1/167

(52) U.S. Cl. CPC G02F 1/133512; G02F 1/1323; G02F 1/167

(57) ABSTRACT

An optical path control member according to an embodiment includes a first substrate; a light conversion unit disposed on the first substrate; a second substrate disposed on the light conversion unit; and a second electrode disposed between the second substrate and the light conversion unit, wherein the light conversion unit includes a partition wall part and a receiving part which are alternately disposed, wherein the partition wall part includes a first electrode, wherein a light conversion material is disposed inside the receiving part, and wherein a width of the partition wall part is smaller than a width of the receiving part.

### Technical Field

An embodiment relates to an optical path control member and a display device comprising the same.

### BACKGROUND ART

An optical path control member is a light blocking film that changes a path and transmittance of light emitted from a light source. The optical path control member is attached to a front of a display panel, which is a display device used in a mobile phone, a laptop, a tablet PC, a vehicle navigation system, or a vehicle touch screen. The optical path control member can be attached to the display panel to adjust an emission angle of light.

Alternatively, the optical path control member is used on a window of a vehicle or a building. The optical path control member partially blocks external light to prevent glare. Alternatively, the optical path control member prevents an inside from being seen from an outside. The optical path control member can be attached to an outside of a window of a vehicle or a building to adjust the transmittance of light.

The optical path control member fills a light conversion material inside a light conversion unit. The light conversion material includes light conversion particles. The light conversion unit is converted into a light transmitting unit and a light blocking unit by dispersion and aggregation of the light conversion particles.

The optical path control member includes a first electrode and a second electrode for movement of the light conversion particles. In addition, a process for forming a receiving part in which the light conversion particles are received in a resin layer is required. In addition, a buffer layer for adhesion between the resin layer and the electrode is required.

Accordingly, the optical path control member includes a plurality of layers. As a result, a process of manufacturing the optical path control member becomes complicated. In addition, a thickness of the optical path control member becomes thicker.

Therefore, a new structure of the optical path control member and a driving method thereof that can solve the above problems are required.

Meanwhile, technology related to the optical path control member is disclosed in Korean Publication No. KR10-2022-0032758.

### DISCLOSURE

### Technical Problem

An embodiment provides an optical path control member capable of reducing a thickness.

The embodiment provides an optical path control member having improved driving characteristics.

### Technical Solution

An optical path control member according to an embodiment includes a first substrate; a light conversion unit disposed on the first substrate; a second substrate disposed on the light conversion unit; and a second electrode disposed between the second substrate and the light conversion unit, wherein the light conversion unit includes a partition wall part and a receiving part which are alternately disposed, wherein the partition wall part includes a first electrode, wherein a light conversion material is disposed inside the receiving part, and wherein a width of the partition wall part is smaller than a width of the receiving part.

### Advantageous Effects

The optical path control member according to the embodiment includes a light conversion unit. The light conversion unit includes a partition wall part. In addition, the partition wall part includes a conductive material. For example, the partition wall part may include a metal.

Accordingly, when voltage is applied to the partition wall part, the light conversion particles disposed inside the receiving part move in a direction toward a side surface of the partition wall part.

Therefore, the optical path control member according to the embodiment does not require a lower electrode or an upper electrode. Therefore, the optical path control member according to the embodiment is easily manufactured. In addition, the optical path control member according to the embodiment is formed with a slim thickness.

In addition, the partition wall part may be formed in a pattern of various shapes.

For example, the partition wall part may include a protrusion. Accordingly, when the optical path control member is applied to a display device, a window of a building, or a window of a car, the light conversion particles are prevented from settling in a gravity direction.

In addition, driving characteristics of the optical path control member are improved.

In addition, the partition wall part may be formed in a curved shape, a random shape, or a mesh shape. Accordingly, when the optical path control member is applied to the display device, it is possible to prevent a moire phenomenon due to overlapping of a pixel pattern of the display panel and a pattern of the partition wall part. Accordingly, the user's visibility is improved.

In addition, the partition wall part has an area, width, and thickness within a set range.

Accordingly, the reliability of the partition wall part is improved. In addition, the light transmittance is controlled by the partition wall part. Accordingly, the optical path control member has a light transmittance within a set range in each mode.

### DESCRIPTION OF DRAWINGS

FIG. 1 is a perspective view of an optical path control member according to an embodiment.

FIG. 2 is a cross-sectional view taken along A-A′ region of FIG. 1.

FIG. 3 is a cross-sectional view taken along B-B′ region of FIG. 1.

FIG. 4 and FIG. 5 are other cross-sectional views taken along A-A′ region of FIG. 1.

FIGS. 6 to 8 are enlarged views of a region A of FIG. 2.

FIGS. 9 to 12 are enlarged views of a region B of FIG. 2.

FIGS. 13 to 25 are top views of a first substrate for explaining various shapes of a partition wall part of an optical path control member according to an embodiment.

FIGS. 26 to 28 are top views of a first substrate for explaining a connection between a partition wall part of an optical path control member and a printed circuit board according to an embodiment.

FIGS. 29 and 30 are cross-sectional views of a display device to which an optical path control member according to an embodiment is applied.

FIGS. 31 to 35 are views for explaining one embodiment of a display device to which an optical path control member according to an embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to the drawings.

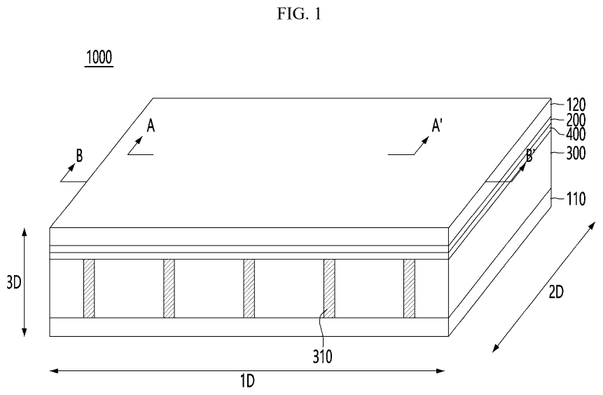

Referring to FIGS. 1 to 12, the optical path control member 1000 includes a first substrate 110, a second substrate 120, an electrode, and a light conversion unit 300. In addition, the optical path control member 1000 may further include an adhesive layer 400 and a sealing part.

The first substrate 110 supports the light conversion unit 300. The first substrate 110 may be rigid or flexible.

In addition, the first substrate 110 may be transparent. For example, the first substrate 110 may include a transparent substrate capable of transmitting light.

The first substrate 110 may include a glass, a plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS). This is an example and is not limited thereto.

In addition, the first substrate 110 may be a flexible substrate having flexible characteristics.

In addition, the first substrate 110 may be a curved or bent substrate. That is, the optical path control member including the first substrate 110 may also be formed to have flexible, curved or bent characteristics. Accordingly, the optical path control member may be changed into various designs.

The first substrate 110 is defined in a first direction 1D, a second direction 2D, and a third direction 3D. The first direction 1D, the second direction 2D, and the third direction 3D are different directions.

The first direction 1D and the second direction 2D correspond to a length or width direction of the first substrate 110. In addition, the third direction 3D corresponds to a thickness direction of the first substrate 110.

For example, the first direction 1D is defined in a length direction of the first substrate 110. In addition, the second direction 2D is defined in a width direction of the first substrate 110. In addition, the third direction 3D is defined in a thickness direction of the first substrate 110.

Alternatively, the first direction 1D is defined in a width direction of the first substrate 110. Alternatively, the second direction 2D is defined in a length direction of the first substrate 110. Alternatively, the third direction 3D is defined in a thickness direction of the first substrate 110.

Hereinafter, the first direction 1D is defined in a length direction of the first substrate 110 for convenience of explanation. In addition, the second direction 2D is defined in the width direction of the first substrate 110. In addition, the third direction 3D is defined in the thickness direction of the first substrate 110.

The first substrate 110 may have a thickness within a set range. For example, the first substrate 110 may have a thickness of 25 μm to 150 μm.

The second substrate 120 is disposed on the first substrate 110.

The second substrate 120 supports the second electrode 200. The second substrate 120 may be rigid or flexible.

In addition, the second substrate 120 may be transparent. For example, the second substrate 120 may include a transparent substrate that can transmit light.

For example, the second substrate 120 may include a material identical to or similar to the first substrate 110 described above.

In addition, the second substrate 120 may be a flexible substrate having flexible characteristics. In addition, the second substrate 120 may be a curved or bent substrate.

The second substrate 120 may be defined in a first direction 1D, a second direction 2D, and a third direction 3D.

Hereinafter, the first direction 1D is defined in the length direction of the second substrate 120 for convenience of explanation. In addition, the second direction 2D is defined in the width direction of the second substrate 120. In addition, the third direction 3D is defined in the thickness direction of the second substrate 120.

The second substrate 120 may have a thickness within a set range. For example, the second substrate 120 may have a thickness of 25 μm to 150 μm.

The second electrode 200 is disposed on one surface of the second substrate 120. In detail, the second electrode 200 is disposed on a lower surface of the second substrate 120. That is, the second electrode 200 is disposed between the first substrate 110 and the second substrate 120.

The second electrode 200 may include a conductive material. For example, the second electrode 200 may include a transparent conductive material. For example, the second electrode 200 may include a conductive material having a light transmittance of about 80% or more. For example, the second electrode 200 may include a metal oxide such as indium tin oxide, indium zinc oxide, copper oxide, tin oxide, zinc oxide, or titanium oxide.

The second electrode 200 may be formed with a thickness within a set range. For example, the second electrode 200 may have a thickness of about 10 nm to about 300 nm.

Alternatively, the second electrode 200 may include various metals to implement low resistance. For example, the second electrode 200 may include at least one metal among chromium (Cr), nickel (Ni), copper (Cu), aluminum (Al), silver (Ag), molybdenum (Mo), gold (Au), titanium (Ti), and alloys thereof.

The second electrode 200 may be disposed on an entire surface of one surface of the second substrate 120. In detail, the second electrode 200 may be disposed as a surface electrode on one surface of the second substrate 120.

Alternatively, the second electrode 200 may be disposed as a pattern electrode on one surface of the second substrate 120. That is, the second electrode 200 may be disposed as a plurality of pattern electrodes spaced apart from each other on one surface of the second substrate 120.

In addition, the second electrode 200 may be formed in a mesh shape including an opening. Accordingly, even if the second electrode 200 includes metal, the electrode may not be visible from an outside, thereby improving visibility. In addition, since the light transmittance increases by the opening, a brightness of the optical path control member may be improved.

In addition, the second electrode 200 is disposed between the partition wall part 310 described below and the second substrate 120. Accordingly, the second electrode 200 is formed on an entire surface of the second substrate 120 in one process. Therefore, the process efficiency of the optical path control member is improved. In addition, the second electrode 200 is separated from the first electrode 310a of the partition wall part 310 by an adhesive layer 400. Therefore, a current conduction between the first electrode and the second electrode is prevented.

The light conversion unit 300 is disposed between the first substrate 110 and the second substrate 120. In detail, the light conversion unit 300 is disposed between the first substrate 110 and the electrode 200. More specifically, the light conversion unit 300 is disposed between the first substrate 110 and the adhesive layer 400. In addition, the light conversion unit 300 is in direct contact with the first substrate 110.

A size of the light conversion unit 300 may be the same as or different from a size of at least one of the first substrate 110 and the second substrate 120.

For example, a size of the light conversion unit 300 may be the same as or similar to a size of at least one of the first substrate 110 and the second substrate 120. Being similar means being equal in a tolerance range. In detail, the size (e.g., area) of a lower surface of the light conversion unit 300 may be the same as or similar to a size (e.g., area) of an upper surface of the first substrate 110. In addition, a size (e.g., area) of an upper surface of the light conversion unit 300 may be the same as or similar to a size (e.g., area) of a lower surface of the second substrate 120.

Alternatively, the size of the light conversion unit 300 may be different from the size of at least one of the first substrate 110 and the second substrate 120. In detail, the size (e.g., area) of the lower surface of the light conversion unit 300 may be smaller than the size (e.g., area) of the upper surface of the first substrate 110. In addition, the size (e.g., area) of the upper surface of the light conversion unit 300 may be smaller or greater than the size (e.g., area) of the lower surface of the second substrate 120.

The adhesive layer 400 is interposed between the light conversion unit 300 and the second substrate 120. The light conversion unit 300 and the second substrate 120 are adhered by the adhesive layer 400. In detail, the light conversion unit 300 and the second electrode 200 are adhered by the adhesive layer 400.

The adhesive layer 400 may include a light-transmitting material. For example, the adhesive layer 400 may include an optical clear adhesive. In addition, the adhesive layer 400 may have a thickness within a set range. For example, the adhesive layer 400 may have a thickness of 50 μm or less. When the thickness of the adhesive layer 400 exceeds 50 μm, the overall thickness of the optical path control member increases.

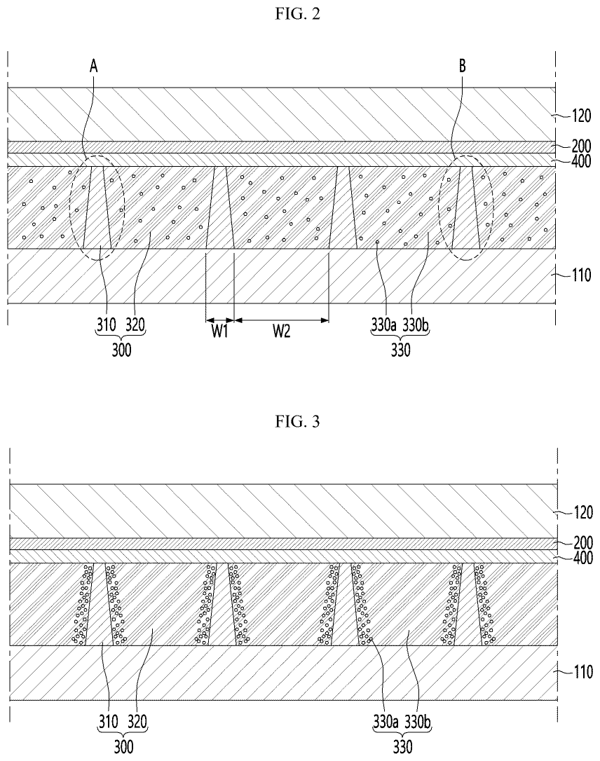

Referring to FIGS. 2 and 3, the light conversion unit 300 includes a partition wall part 310 and a receiving part 320.

The partition wall part 310 is defined as a partition region that separates the receiving parts. The partition wall part 310 blocks light. Therefore, light moving from the first substrate 110 toward the second substrate 120 or light moving from the second substrate 120 toward the first substrate 110 is blocked by the partition wall part. That is, the partition wall part 310 is a region of the light conversion unit 300 where light is blocked.

The partition wall part 310 and the receiving part 320 are disposed with different widths. For example, a width of the partition wall part 310 may be smaller than a width of the receiving part 320. For example, a width W2 of the receiving part 320 may be at least twice a width W1 of the partition wall part. In detail, the width W2 of the receiving part 320 may be at least three times the width W1 of the partition wall part. The width W2 of the receiving part 320 may be at least 5 times the width W1 of the partition wall part.

The partition wall part 310 and the receiving part 320 are alternately disposed. That is, each partition wall part 310 is disposed between adjacent receiving parts 320. In addition, each receiving part 320 is disposed between adjacent partition wall parts 310.

The partition wall part 310 may include an opaque material. The partition wall part 310 may include a material that does not transmit light. That is, a light transmittance of the partition wall part may be lower than a light transmittance of the receiving part.

For example, the partition wall part 310 may include a conductive material. For example, the partition wall part 310 may include a metal. Accordingly, the partition wall part 310 may serve as an electrode. That is, the partition wall part 310 includes a conductive material through which current can flow. Accordingly, a voltage can be applied toward the receiving part 320 through the partition wall part 310.

That is, the partition wall part 310 separates the receiving parts 310 and transmits the voltage to the light conversion material 330 disposed inside the receiving part 310. That is, the partition wall part 310 may be an electrode and a partition wall.

The partition wall part 310 may be formed in a plurality of pattern shapes. In detail, the partition wall part 310 may include a plurality of pattern parts. More specifically, the partition wall part 310 may include a plurality of pattern parts spaced apart from each other.

The receiving part 320 is formed between the plurality of pattern parts. In addition, the light conversion material 330 is disposed inside the receiving part 320.

A size, layer structure, and pattern shape of the partition wall part 310 will be described in detail below.

The light conversion material 330 is disposed in the receiving part 320. The light conversion material 330 includes light conversion particles 330a and a dispersion liquid 330b. The light conversion particles 330a are disposed inside the dispersion liquid 330b.

The dispersion liquid 330b may include a material that disperses the light conversion particles 330a. The dispersion liquid 330b may include a transparent material. The dispersion liquid 330b may include a nonpolar solvent. In addition, the dispersion liquid 330b may include a material that can transmit light. For example, the dispersion liquid 330b may include at least one material among a halocarbon oil, a paraffin oil, and an isopropyl alcohol.

The light conversion particles 330a are disposed inside the dispersion liquid 330b. In detail, the plurality of light conversion particles 330a are disposed by being dispersed or aggregated inside the dispersion liquid 330b.

The light conversion particles 330a may include a material capable of absorbing light. That is, the light conversion particles 330a may be light absorbing particles. The light conversion particles 330a may have a color. For example, the light conversion particles 330a may have a black color. For example, the light conversion particles 330a may include carbon black particles.

A surface of the light conversion particles 330a may be charged. Accordingly, the light conversion particles 330a may have polarity. For example, the surface of the light conversion particles 330a may be charged with a negative charge. Accordingly, when voltage is applied to the optical path control member, the light conversion particles 330a move inside the receiving part 320.

The light transmittance of the receiving part 320 changes due to the light conversion particles 330a. In detail, the receiving part 320 can be converted into a light blocking part and a light transmitting part by changing the light transmittance by the light conversion particles 330a. That is, the transmittance of light passing through the receiving part 320 is changed by dispersion or aggregation of the light conversion particles 330a.

For example, when the light path member is in an off state, voltage is applied to the second electrode 200 and the partition wall part 310. Accordingly, the optical path control member is switched from a first mode to a second mode. Alternatively, the optical path control member is switched from the second mode to the first mode.

In detail, the receiving part 320 becomes a light blocking part in the first mode. Accordingly, the receiving part 320 blocks light. Accordingly, an external user cannot see a display screen. In addition, light is blocked from the windows of a vehicle or a window of a building. Therefore, the optical path control member operates in a blind mode. That is, the first mode may be a light blocking mode or a blind mode.

In addition, the receiving part 320 becomes a light transmitting part in the second mode. Accordingly, the receiving part 320 transmits light. Accordingly, an external user can see the display screen. Accordingly, an external user can use the optical path control member in a privacy mode. In addition, light is transmitted through a vehicle window or a building window. Accordingly, the optical path control member operates in a light mode. That is, the second mode may be a privacy mode or a light mode.

The receiving part 320 is switched to a light blocking part or a light transmitting part by the movement of the light conversion particles 330a. That is, the surface of the light conversion particles 330a has a charge. Accordingly, when voltage is applied, the light conversion particles 330a move toward the partition wall part 310.

For example, when no voltage is applied to the optical path control member from the outside, the light conversion particles 330a are uniformly dispersed in the dispersion liquid 330b. Accordingly, the light of the receiving part 320 is blocked by the light conversion particles 330a. Accordingly, the receiving part 320 is driven as a light blocking part in the first mode.

In addition, when a voltage is applied to the optical path control member from the outside, the light conversion particles 330a move. For example, a positive voltage is applied to the partition wall part 310 and a negative voltage is applied to the second electrode 200. Accordingly, the light conversion particles 330a charged with a negative charge move toward the partition wall part 310. That is, the light conversion particles 330a move toward a left side surface and a right side surface of the receiving part 320.

For example, when a voltage is applied to either the partition wall part 310 or the second electrode 200, an electric field is formed between the partition wall part 310 and the second electrode 200. Accordingly, the light conversion particles 330a charged negatively move toward the partition wall part 310 to which a positive voltage is applied using the dispersion liquid 330b as a medium.

For example, referring to FIG. 2, no voltage is applied to the partition wall part 310 and/or the second electrode 200. That is, the optical path control member is in an initial mode or the first mode. In this case, the light conversion particles 330a are uniformly dispersed within the dispersion liquid 330b. Accordingly, the receiving part 320 is driven as a light blocking part.

Also, referring to FIG. 3, the voltage is applied to the partition wall part 310 and/or the second electrode 200. That is, the optical path control member is in the second mode. In this case, the light conversion particles 330a move toward the partition wall part 310 within the dispersion liquid 330b. Specifically, the light conversion particles 330a move toward a side surface of the partition wall part 310. That is, the light conversion particles 330a move in one direction. Thereby, the receiving part 320 is driven as a light transmitting part.

Accordingly, the optical path control member operates in two modes according to an user's surrounding environment.

For example, the display screen operates in privacy mode and light-blocking mode by the optical path control member. Alternatively, a window of a vehicle or a window of a building operates in a blind mode and a light mode.

Therefore, the optical path control member operates in two modes according to the user's request, and accordingly, the user can use various modes of optical path members.

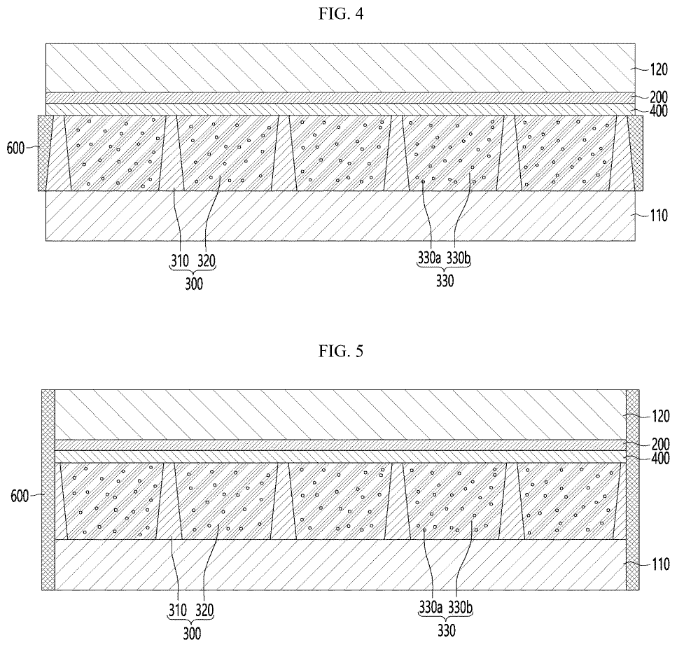

Meanwhile, referring to FIGS. 4 and 5, the optical path control member may include a protective layer 600. Referring to FIG. 4, the protective layer 600 is disposed on a region corresponding to the light conversion unit 300. The protective layer 600 is disposed on an outer surface of the partition wall part 310 disposed at an outermost side. That is, the protective layer 600 is in contact with the partition wall part 310.

In FIG. 4, only the protective layer spaced apart in the first direction 1D is illustrated. However, the embodiment is not limited thereto. The protective layer may include a protective layer spaced apart in the second direction 2D. That is, the protective layer 600 may be disposed to surround the outer surface of the partition wall part 310 disposed at the outermost side.

Alternatively, referring to FIG. 5, the protective layer 600 is disposed on an outermost outer surface of the optical path control member 1000. That is, the protective layer 600 contacts the first substrate 110, the partition wall part 310, the adhesive layer 400, the second electrode 200, and the second substrate 120.

In FIG. 5, only the protective layer spaced apart in the first direction 1D is illustrated. However, the embodiment is not limited thereto. The protective layer may include a protective layer spaced apart in the second direction 2D. That is, the protective layer 600 may be disposed to surround an outermost outer surface of the optical path control member.

The protective layer 600 protects the partition wall part 310. The protective layer 600 is disposed on the partition wall part 310. Accordingly, the protective layer 600 prevents deformation of the partition wall part 310. The partition wall part 310 includes a conductive material such as metal. Therefore, when the partition wall part 310 is exposed to an outside, an outer surface of the partition wall part 310 may be oxidized. Accordingly, the conductivity of the partition wall part 310 is reduced. Accordingly, the driving characteristics of the optical path control may be reduced. In addition, the outer surface of the optical path control member may be contaminated by corrosion of the partition wall part 310.

Therefore, the optical path control member includes a protective layer that protects the partition wall part. Accordingly, oxidation and damage of the partition wall part are prevented. Accordingly, the driving characteristics of the optical path control member can be maintained. In addition, contamination of the outer surface of the optical path control member can be prevented.

In addition, the protective layer 600 is disposed to surround the outer surface of the partition wall part 310. Accordingly, the outer surface of the optical path control member becomes flat. The outer surface of the partition wall part 310 may be inclined during a process of forming. Accordingly, the protective layer 300 is disposed on the outer surface of the partition wall part 310 disposed at the outermost side. Accordingly, the outer surface of the partition wall part becomes flat. That is, the protective layer 600 may be a planarization layer.

The optical path control member according to the embodiment includes a partition wall part that separates the receiving part into a plurality of receiving parts. Additionally, the partition wall part includes a conductive material. Accordingly, the partition wall part becomes a partition wall and an electrode.

Accordingly, a lower electrode disposed on an upper side of the first substrate is omitted. In addition, a buffer layer for bonding the first substrate, the lower electrode, and the light conversion unit is omitted.

Accordingly, the optical path control member according to the embodiment is formed with a slim thickness. In addition, since some layers are omitted, the manufacturing process steps are reduced. Accordingly, the optical path control member according to the embodiment can shorten the manufacturing process time. In addition, the optical path control member according to the embodiment can be easily manufactured.

Hereinafter, the partition wall part of the optical path control member according to the embodiment will be described in detail with reference to the drawings.

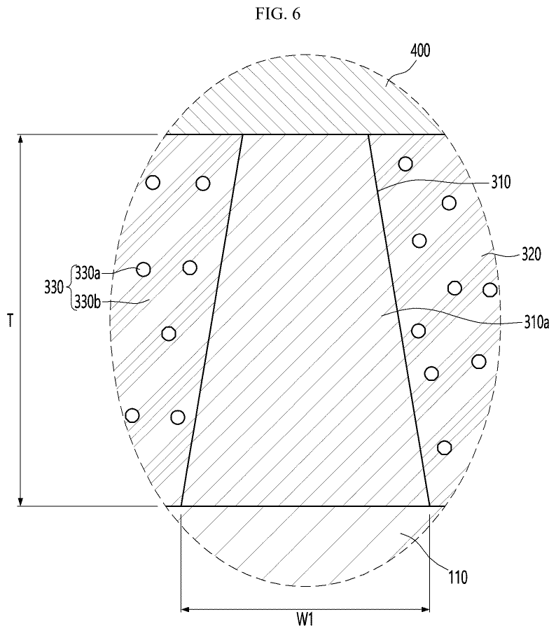

FIGS. 6 to 8 are enlarged views of a region A of FIG. 2. Examples described in FIGS. 6 to 8 are individually applied to the optical path control member according to the embodiment. Alternatively, the examples described in FIGS. 6 to 8 are applied together as multiple examples to the optical path control member according to the embodiment.

Referring to FIGS. 6 to 8, the partition wall part 310 includes a first electrode 310a. The first electrode 310a may include one or more metals. For example, the first electrode 310a may include at least one metal among chromium (Cr), nickel (Ni), copper (Cu), aluminum (Al), silver (Ag), molybdenum (Mo), gold (Au), titanium (Ti), and alloys thereof.

In addition, the partition wall part 310 may include one or more layers. In detail, the first electrode 310a may include one or more layers.

For example, referring to FIG. 6, the first electrode 310a may include one single metal. Accordingly, the partition wall part 310 may be formed as one layer.

For example, the first electrode 310a may be formed by a plating method and/or a deposition method. For example, a seed layer is formed on the first substrate 110. Specifically, a seed layer including copper (Cu) is formed on the first substrate 110. The seed layer may be formed by a deposition or electroless plating process.

Subsequently, the first electrode 310a is formed using the seed layer. For example, the first electrode 310a is formed by an electrolytic plating process using the seed layer. Accordingly, the partition wall part 310 may be formed of a single metal of copper metal.

Accordingly, the partition wall part 310 is easily manufactured. In addition, cracks due to interface mismatch that may occur when using two different metals can be prevented. Therefore, the partition wall part has improved reliability.

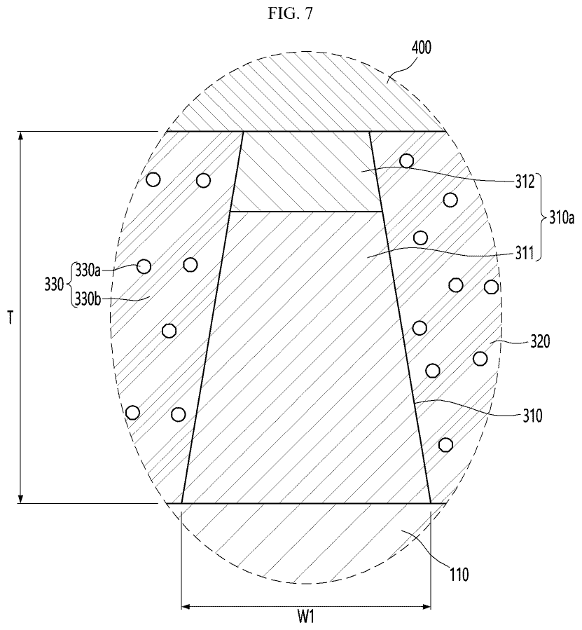

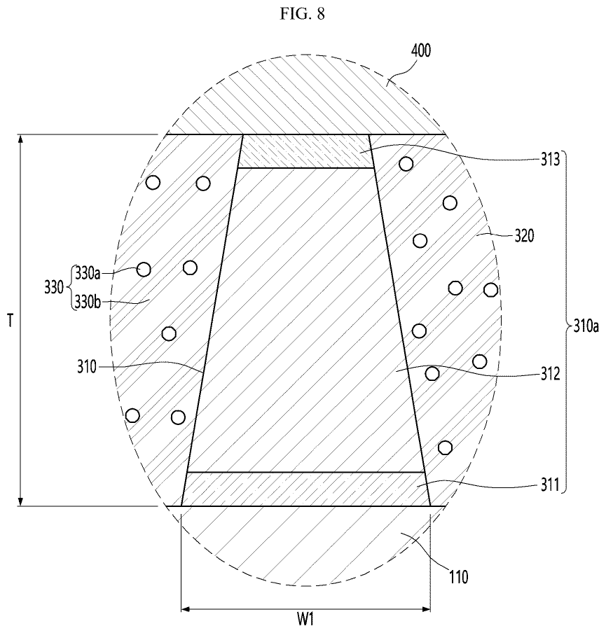

Alternatively, referring to FIG. 7, the partition wall part 310 may include a plurality of metals. For example, the first electrode 310a may include a plurality of metals. Accordingly, the partition wall part 310 may be formed of a plurality of layers. For example, the first electrode 310a may include a first metal layer 311 and a second metal layer 312 on the first metal layer 311.

For example, the partition wall part 310 may be formed by a plating method and/or a deposition method. For example, a seed layer is formed on the first substrate 110. In detail, a seed layer including a first metal is formed on the first substrate 110. The seed layer may be formed by a deposition or electroless plating process.

Subsequently, the first metal layer 311 is formed using the seed layer. For example, the first metal layer 311 is formed by an electrolytic plating process using the seed layer.

Subsequently, the second metal layer 312 is formed on the first metal layer 311. For example, the second metal layer 312 can be formed by depositing a second metal on the first metal layer 311. The first metal and the second metal include different metals.

Accordingly, the partition wall part 310 includes the first metal layer 311 and the second metal layer 312 including different metals.

Accordingly, the reliability of the partition wall part 310 is improved. When the partition wall part 310 is formed using a single metal, the adhesion between the partition wall part 310 and the first substrate 110 may decrease as the thickness of the partition wall part 310 increases. Accordingly, the partition wall part 310 and the first substrate 110 may be separated. Accordingly, the reliability of the optical path control member may be reduced.

Therefore, a first metal layer is formed in a thickness range that can secure adhesion with the first substrate, and a second metal layer is formed on the first metal layer. Accordingly, even if the thickness of the partition wall part increases, the reliability of the partition wall part may be secured.

In addition, the visibility of the optical path control member may be improved due to a difference in physical characteristics between the first metal layer and the second metal layer. For example, the second metal may have a reflectivity smaller than that of the first metal. Accordingly, the light reflected from the partition wall part 310 is reduced. Accordingly, the user's visibility may be improved.

Alternatively, referring to FIG. 8, the partition wall part 310 may include a plurality of metals. For example, the first electrode 310a may include a plurality of metals. Accordingly, the partition wall part 310 may be formed of a plurality of layers. For example, the partition wall part 310 may include a first metal layer 311, a second metal layer 312 on the first metal layer 311, and a third metal layer 313 on the second metal layer 312.

The first electrode 310a may be formed through a deposition method. For example, the first metal layer 311 may be formed by depositing the first metal on the first substrate 110.

Subsequently, the second metal layer 312 may be formed on the first metal layer 311. For example, the second metal layer 312 may be formed by depositing the second metal on the first metal layer 311.

Subsequently, a third metal layer 313 can be formed on the second metal layer 312. For example, a third metal can be deposited on the second metal layer 312 to form the third metal layer 313.

At least one of the first metal, the second metal, and the third metal can contain a material different from at least other one of the first metal, the second metal, and the third metal.

Accordingly, the partition wall part 310 can include a first metal layer 311, a second metal layer 312, and a third metal layer 313 containing different metals.

For example, the first metal and the third metal can be different from the second metal. In addition, the first metal and the third metal can be the same or different.

Accordingly, the reliability of the partition wall part 310 is improved. For example, the first metal layer 311 can be formed of a first metal having good adhesion to the first substrate 110. Subsequently, the second metal layer 312 and the third metal layer 313 can be disposed on the first metal layer 311. Therefore, the first metal layer 311 acts as a buffer layer between the partition wall part 310 and the first substrate 110. Therefore, the adhesion between the partition wall part 310 and the first substrate 110 is improved.

Alternatively, the driving characteristics of the optical path control member 1000 are improved. For example, the second metal layer 312 having a largest thickness can be formed of a second metal having high conductivity. Accordingly, the voltage applied to the partition wall part 310 is transmitted toward the receiving part 320 at a high speed. Accordingly, a driving speed of the optical path control member is increased.

Alternatively, the visibility and brightness of the optical path control member 1000 are improved. For example, the first metal and the third metal may each have a lower reflectivity than the second metal.

Accordingly, the light reflected from the upper surface and the lower surface of the partition wall part is reduced. Accordingly, the amount of light emitted in a direction of an emission surface of the optical path control member is increased. Therefore, the brightness of the optical path control member can be improved. In addition, the visibility of the user can be improved.

Referring to FIGS. 6 to 8, the partition wall part 310 has a width and thickness within a set range.

For example, a thickness (T) of the partition wall part 310 can be formed within a set range. In detail, the thickness (T) of the partition wall part 310 can be 5 μm or more. In more detail, the thickness (T) of the partition wall part 310 can be 5 μm to 100 μm. In more detail, the thickness (T) of the partition wall part 310 can be 15 μm to 70 μm. In more detail, the thickness (T) of the partition wall part 310 can be 25 μm to 50 μm.

If the thickness (T) of the partition wall part 310 is smaller than 5 μm, the thickness of the receiving part 320 also decreases. Accordingly, a height of the light conversion material decreases. Therefore, blocking characteristic of the optical path control member can decrease. In addition, if the thickness (T) of the partition wall part 310 exceeds 100 μm, the thickness of the receiving part 320 also increases. Accordingly, the height of the light conversion material increases. Therefore, a driving voltage of the optical path control member can increase.

The width W1 of the partition wall part 310 may be 30 μm or less. When the width of the partition wall part changes according to the height of the partition wall part 310, the width W1 of the partition wall part means a maximum width of the partition wall part.

In addition, a ratio of the width W1 and the thickness (T) of the partition wall part 310 has a set range. In detail, a ratio (T/W1) of the thickness (T) to the width W1 may be 10 or less. More specifically, a ratio (T/W1) of the thickness (T) to the width W1 may be 5 or less. In more detail, a ratio (T/W1) of the thickness (T) to the width W1 may be 3 or less. In more detail, a ratio (T/W1) of the thickness (T) to the width W1 may be 1 to 10.

If the ratio (T/W1) of the thickness (T) to the width WI is less than 1, the thickness of the partition wall part 310 decreases. Accordingly, the amount of light conversion material disposed inside the receiving part 320 decreases. Accordingly, the blocking characteristic of the optical path control member decreases. In addition, since the width of the partition wall part 310 increases, the light transmittance of the optical path control member decreases. Accordingly, the brightness of the optical path control member decreases.

If the ratio (T/W1) of the thickness (T) to the width W1 exceeds 10, the thickness of the partition wall part 310 increases. Accordingly, the amount of light conversion material disposed inside the receiving part 320 increases. Accordingly, the driving voltage of the optical path control member increases. In addition, since the width of the partition wall part 310 decreases, a support force of the partition wall part 310 decreases. Accordingly, the adhesive force between the partition wall part and the first substrate 110 decreases. Accordingly, the reliability of the optical path control member decreases.

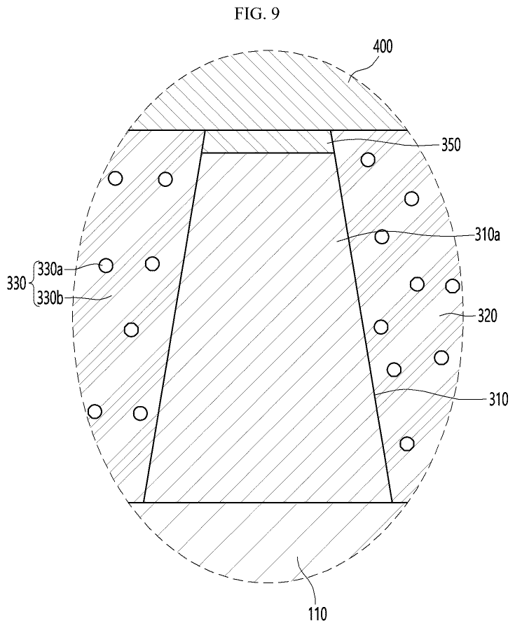

FIGS. 9 to 12 are enlarged views of a region B of FIG. 2. The examples described in FIGS. 9 to 12 are individually applied to the optical path control member according to the embodiment. Alternatively, the examples described in FIGS. 9 to 12 are applied together as multiple examples to the optical path control member according to the embodiment.

Referring to FIGS. 9 to 12, the partition wall part 310 includes an insulating layer 350. In detail, the insulating layer 350 is disposed on the first electrode 310a. The insulating layer 350 may be an oxide layer. The insulating layer 350 may be an antireflection layer. The insulating layer 350 may be a black oxide layer. The insulating layer 350 may be a low-reflection layer. The insulating layer 350 may be a high-intensity layer. The insulating layer 350 may be disposed on at least one of the upper surface, the lower surface, and the side surface of the partition wall part 310.

Referring to FIG. 9, the insulating layer 350 may be disposed on the upper surface of the partition wall part 310. In detail, the insulating layer 350 may be disposed on the upper surface of the first electrode 310a. More specifically, the insulating layer 350 may be disposed between the first electrode 310a and the adhesive layer 400. The insulating layer 350 may be formed integrally with the first electrode 310a. That is, the insulating layer 350 may be formed by oxidizing a portion of the first electrode 310a.

The reflectivity of the insulating layer 350 and the reflectivity of the first electrode 310a may be different. In detail, the reflectivity of the insulating layer 350 may be lower than the reflectivity of the first electrode 310a. For example, the reflectivity of the insulating layer 350 may be 70% or less of the reflectivity of the first electrode 310a.

Accordingly, when light is emitted from the first substrate 110 toward the second substrate 120, the amount of light reflected from an upper portion of the partition wall part 310 is reduced. Accordingly, the user's visibility is improved.

A surface roughness of the insulating layer 350 and a surface roughness of the first electrode 310a may be different. In detail, the surface roughness of the insulating layer 350 may be greater than the surface roughness of the first electrode 310a.

Accordingly, the adhesive strength between the partition wall part 310 and the second electrode 200 increases. That is, since the surface roughness of the insulating layer 350 increases, a contact area between the insulating layer 350 and the adhesive layer 400 increases. Accordingly, the adhesive strength between the insulating layer 350 and the adhesive layer 400 increases. Therefore, the adhesive strength between the partition wall part 310 and the second electrode 200 is improved.

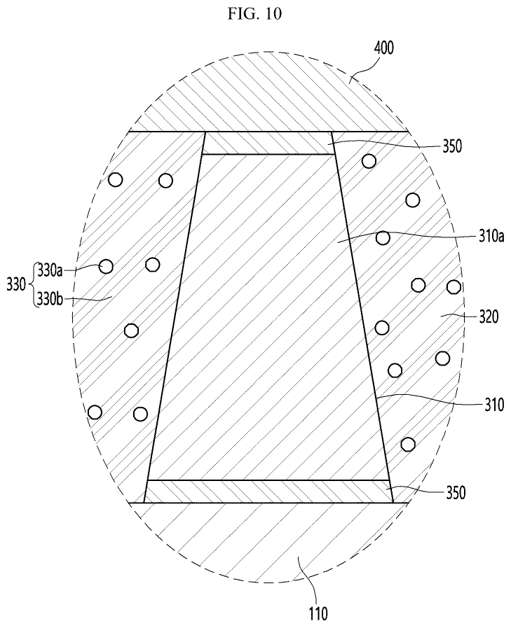

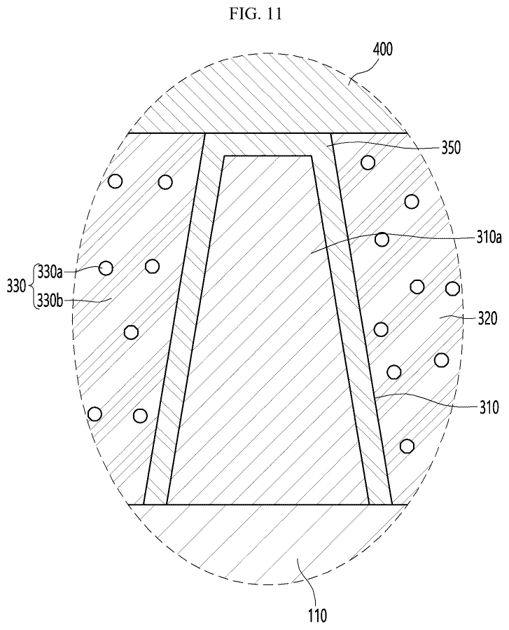

Referring to FIG. 10, the insulating layer 350 may be disposed on the upper and lower portions of the partition wall part 310. In detail, the insulating layer 350 may be disposed on the upper and lower portions of the first electrode 310a. In detail, the insulating layer 350 may be disposed between the first electrode 310a and the adhesive layer 400. In addition, the insulating layer 350 may be disposed between the first electrode 310a and the first substrate 110.

Since the insulating layer 350 is also disposed on a lower portion of the partition wall part 310, the light transmittance of the optical path control member is improved. That is, when light moves from the first substrate 110 toward the second substrate 120, the amount of light reflected from the lower portion of the partition wall part 310 is reduced. Accordingly, the brightness of the optical path control member is improved.

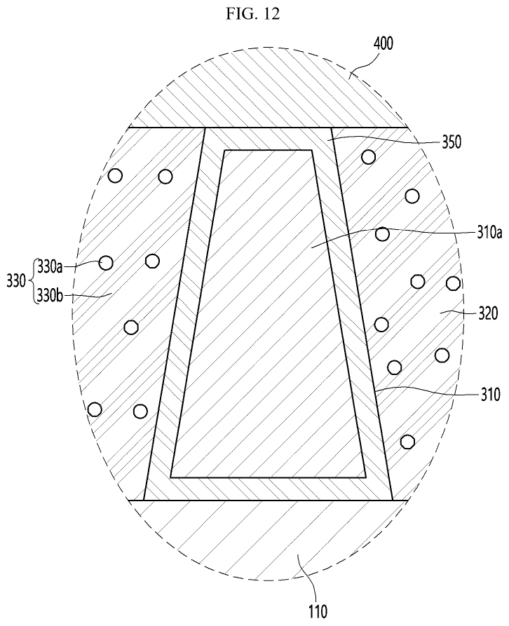

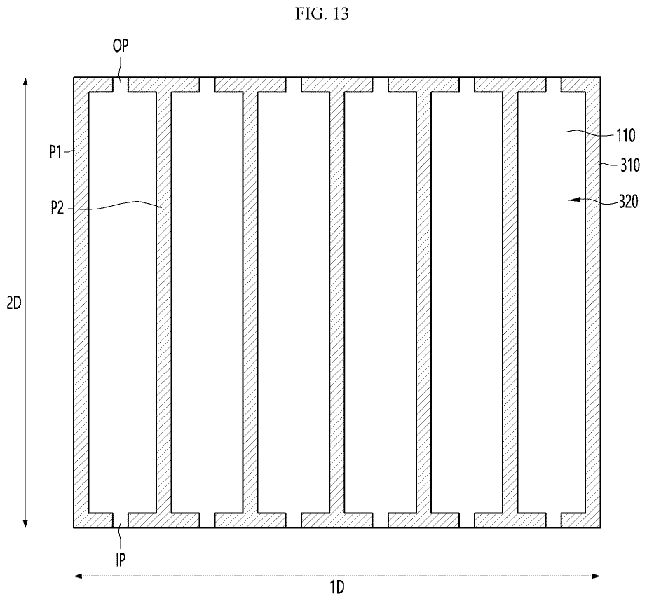

Referring to FIGS. 11 and 12, the insulating layer 350 may also be disposed at a side portion of the partition wall part 310. For example, referring to FIG. 11, the insulating layer 350 may be disposed on upper and lower sides of the first electrode 310a. Alternatively, referring to FIG. 12, the insulating layer 350 may be disposed on the upper, lower, and side portions of the first electrode 310a. That is, the insulating layer 350 may be disposed to surround the first electrode 310a.

Since the insulating layer 350 is also disposed on a side portion of the partition wall part 310, the light transmittance of the optical path control member is improved. That is, when light moves from the first substrate 110 toward the second substrate 120, the light reflected from a side portion of the partition wall part 310 is scattered. Accordingly, a decrease in light transmittance can be prevented. Accordingly, the brightness of the optical path control member is improved.

FIGS. 13 to 21 are views for explaining various shapes of a partition wall part 310. FIGS. 13 to 21 are top views of the first substrate 110 on which the partition wall part 310 is disposed.

Referring to FIG. 13, the partition wall part 310 is disposed on the first substrate 110. In detail, the partition wall part 310 is in direct contact with the first substrate 110.

The partition wall part 310 includes a first pattern part P1 and a second pattern part P2. The first pattern part P1 is disposed in an edge region of the first substrate 110. The first pattern part P1 is a pattern part disposed at an outermost side. For example, the first pattern part P1 may extend along an edge of the first substrate 110. Alternatively, the first pattern part P1 may be disposed on at least one of the edges of the first substrate 110. The second pattern part P2 is disposed inside the first substrate 110. The second pattern part P2 is disposed inside the first pattern part P1.

The first pattern part P1 and the second pattern part P2 are spaced apart. In addition, the second pattern parts P2 are spaced apart. For example, the second pattern part P2 extends in the second direction 2D. In addition, the second pattern part P2 is spaced apart in the first direction ID. Accordingly, the receiving part 320 is formed between the second pattern parts P2. Accordingly, a plurality of receiving parts 320 are disposed by the partition wall part 310. In addition, the plurality of receiving parts 320 are separated from each other by the partition wall part 310.

The first pattern part P1 includes an injection part IP and an outlet part OP. The injection part IP and the outlet part OP are formed by a hole formed in the first pattern part P1. The injection part IP and the outlet part OP can be formed in a region corresponding to the receiving part 320. Accordingly, the light conversion material is injected in the receiving part 310 by the injection part IP. In addition, the light conversion material is sucked by the outlet part OP. Accordingly, the light conversion material is disposed inside the receiving part 320.

Meanwhile, after the light conversion material 330 is disposed inside the receiving part 320, the injection part IP and the outlet part OP are sealed by the sealing part.

The second pattern part P2 may be disposed in a stripe shape. That is, the second pattern part P2 may extend in a straight line shape. Accordingly, the plurality of receiving parts 320 may be formed with similar areas. Accordingly, a deviation in the areas of the plurality of receiving parts 320 is reduced. Accordingly, the amount of the light conversion material 330 disposed inside the plurality of receiving parts 320 also becomes similar. Accordingly, a difference in the light transmittance of the plurality of receiving parts 320 is reduced. Accordingly, the optical path control member may have uniform light blocking characteristics and transmission characteristics. Accordingly, the user's visibility is improved.

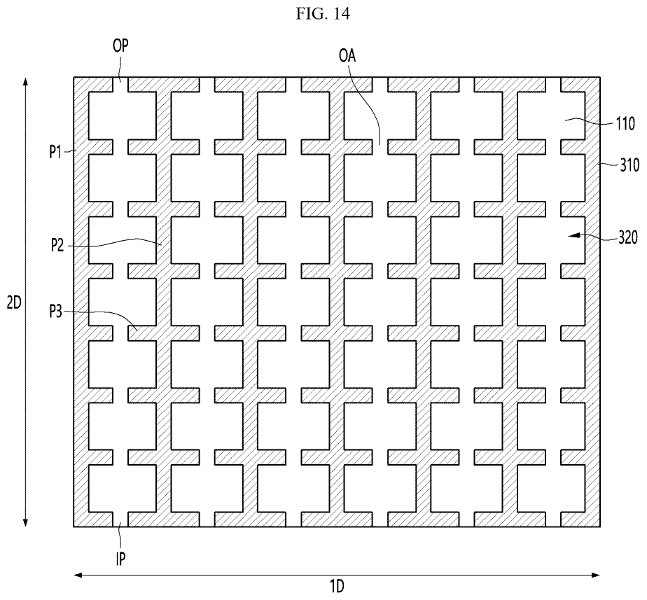

Referring to FIG. 14, the partition wall part 310 further includes a third pattern part P3.

The third pattern part P3 is disposed inside the first substrate 110. The third pattern part P3 is disposed inside the first pattern part P1. The third pattern part P3 protrudes from at least one pattern part among the first pattern part P1 and the second pattern part P2.

The first pattern part P1 and the second pattern part P2 are spaced apart from each other. In addition, the third pattern part P3 is connected to at least one pattern part among the first pattern part P1 and the second pattern part P2. In FIG. 14, the third pattern part P3 is illustrated as being connected to both the first pattern part P1 and the second pattern part P2. However, the embodiment is not limited thereto. That is, the third pattern part P3 can be connected only with the first pattern part P1. Alternatively, the third pattern part P3 can be connected only with the second pattern part P2.

The third pattern part P3 extends in the first direction 1D. That is, a width of the third pattern part P3 is a width in the second direction 2D. In addition, a length of the third pattern part P3 is a length in the first direction 1D.

At least one third pattern part P3 is disposed in the receiving part 320. In addition, the third pattern part P3 is spaced apart from an adjacent third pattern part P3 inside the receiving part 320. In detail, the third pattern part P3 is spaced apart in the first direction 1D. Accordingly, an open region OA is formed between adjacent third pattern parts P3. In detail, the third pattern part P3 is disposed inside the receiving part 320, and the open region OA is disposed inside the receiving part 320.

The light conversion material 330 is disposed inside the receiving part 320 by the open region OA. That is, the light conversion material 330 is injected from the injection part IP and sucked from the outlet part OP. Accordingly, the light conversion material moves from the injection part IP toward the outlet part OP by the open region. Thereby, the light conversion material is disposed inside the receiving part 320.

Meanwhile, precipitation of the light conversion parts 330a is prevented by the third pattern part P3. The optical path control member is attached to a screen of a display device and used. Alternatively, the optical path control member is used by being attached to a window of a vehicle or a building. Accordingly, gravity can be transmitted to the optical path control member in the second direction 2D. Accordingly, the light conversion particles 330a disposed inside the receiving part 320 can settle downward in the second direction 2D. Accordingly, the light conversion particles aggregated in the second direction can be recognized from the outside. In addition, the driving characteristics of the optical path control member can be reduced.

Precipitation of the light conversion parts 330a is prevented by the third pattern part P3. That is, the third pattern part P3 prevents the precipitation of the light conversion particles 330a. Alternatively, a precipitation speed of the light conversion particles 330a is reduced by the third pattern part P3.

Accordingly, the optical path control member according to the embodiment has improved visibility and driving characteristics.

The open region OA has a set size. In detail, a width (width in the first direction) of the open region OA may be 0.5 to 5 times a width (width in the first direction) of the second pattern part P2. In more detail, a width (width in the first direction) of the open region OA may be 1 to 3 times a width (width in the first direction) of the second pattern part P2. In more detail, a width (width in the first direction) of the open region OA may be 1.5 to 2.5 times a width (width in the first direction) of the second pattern part P2.

If the width of the open region OA is less than 0.5 times the width of the second pattern part P2, it may not be easy to move the light conversion material when the light conversion material is injected into the receiving part. Accordingly, a region in which the light conversion material is not disposed may be formed inside the receiving part. Alternatively, it may take a long time to fill the light conversion material inside the receiving part.

If the width of the open region OA is more than 5 times the width of the second pattern part P2, precipitation of the light conversion particles cannot be effectively prevented. Accordingly, the visibility or driving characteristics of the optical path control member may be reduced.

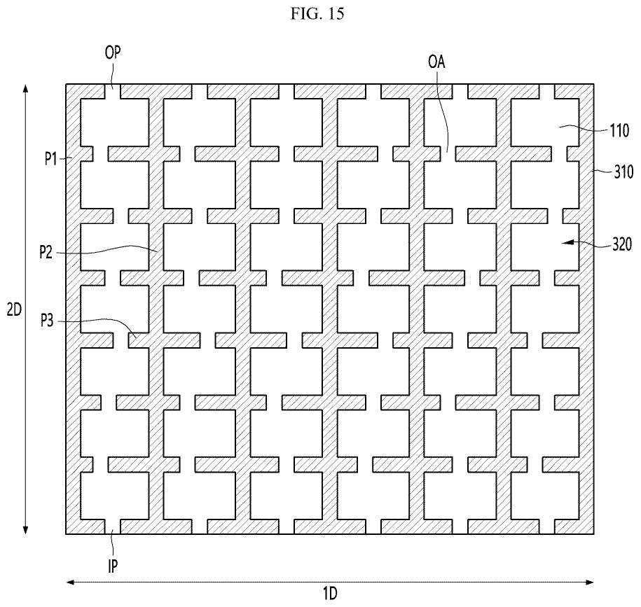

Referring to FIG. 15, the partition wall part 310 further includes a third pattern part P3. In addition, the open regions OA are alternately disposed.

In detail, the open regions OA are alternately disposed in the second direction 2D. That is, the adjacent open region OA in one receiving part 320 is alternately disposed in the second direction 2D. In detail, adjacent open regions OA do not overlap in the second direction 2D. Alternatively, adjacent open regions OA partially overlap in the second direction 2D.

Accordingly, the filling characteristics of the light conversion material disposed within the receiving part 320 are improved. In detail, the light conversion material is injected from the injection part IP and sucked from the outlet part OP. At this time, when the open regions OA are all overlapped in one direction, the pressure of the open region having a narrow width increases. As a result, filling defects may occur around the open region or the open region.

The optical path control member according to an embodiment arranges the positions of the open regions alternately. Accordingly, the suction force by the suction unit may be dispersed. Accordingly, the filling characteristic of the light conversion material is improved.

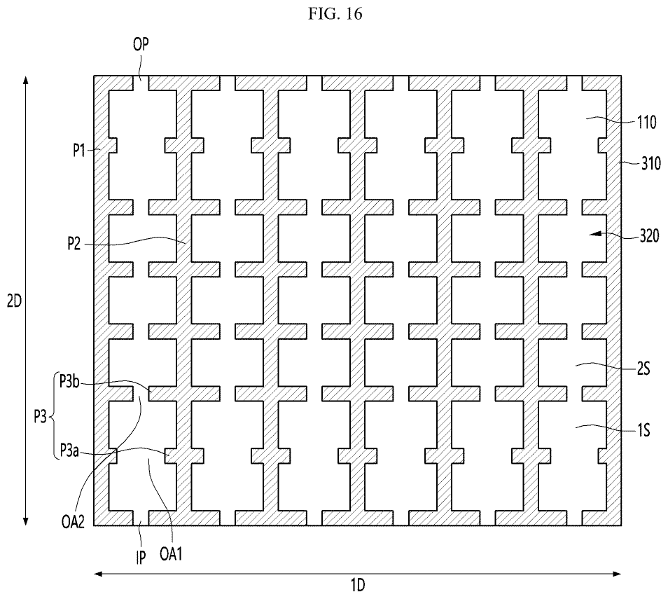

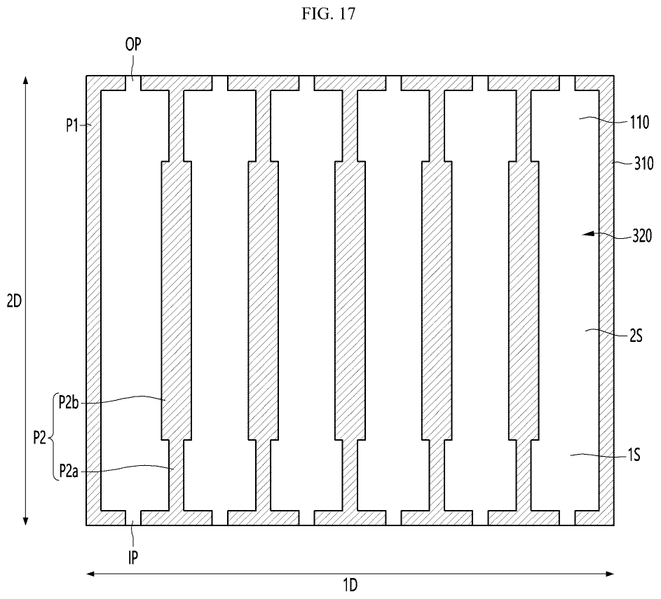

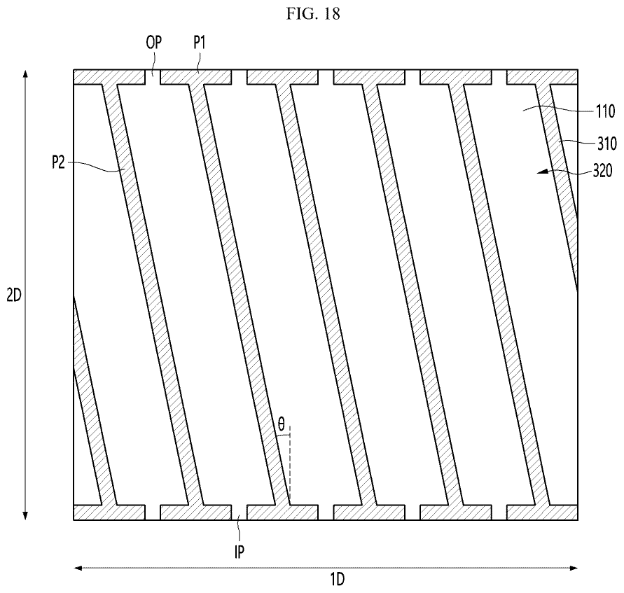

Referring to FIGS. 16 and 17, the receiving part 320 is formed with different areas for each region. In detail, the receiving part 320 changes in width while extending in the second direction 2D. In detail, areas of an outer region and a central region in one receiving part 320 may be different.

Referring to FIG. 16, the third pattern part P3 includes a third-first pattern part P3a and a third-second pattern part P3b. The third-first pattern part P3a is disposed close to the first pattern part P1. The third-second pattern part P3b is disposed farther away from the first pattern part P1.

The third-first pattern part P3a is disposed closer to the first pattern part P1 than the third-second pattern part P3b.

The third-first pattern part P3a and the third-second pattern part P3b have different lengths. In detail, the length of the third-first pattern part P3a is shorter than the length of the third-second pattern part P3b. In addition, a spacing of the third-first pattern part P3a is different from a spacing of the third-second pattern part P3b. In detail, the spacing of the third-first pattern part P3a is larger than the spacing of the third-second pattern part P3b. That is, the partition wall part 310 includes a first open region OA1 and the second open region OA2. In addition, a size of the first open region OA1 and a size of the second open region OA2 are different.

Accordingly, an unit area of the receiving part 320 changes toward the first pattern part P1 in the second direction 2D. In detail, an unit area 1S of a receiving part close to the first pattern part P1 is larger than an unit area 2S of a receiving part far from the first pattern part P1.

In addition, referring to FIG. 17, the second pattern parts P2 have different widths. In detail, the width of the second pattern part P2 changes as it extends in the second direction 2D.

In detail, the second pattern part P2 includes a second-first pattern part P2a and a second-second pattern part P2b. The second-first pattern part P2a is disposed close to the first pattern part P1. The second-second pattern part P2b is disposed far from the first pattern part P1.

The second-first pattern part P2a is disposed closer to the first pattern part P1 than the second-second pattern part P2b.

The second-first pattern part P2a and the second-second pattern part P2b have different widths. In detail, the width of the second-first pattern part P2a is smaller than the width of the second-second pattern part P2b.

Accordingly, an unit area of the receiving part changes toward the first pattern part P1 in the second direction 2D. In detail, an unit area 1S of a receiving part close to the first pattern part P1 is larger than an unit area 2S of a receiving part far from the first pattern part P1.

Accordingly, when the optical path control member is driven in the privacy mode or the light mode, the brightness uniformity of the optical path control member is improved. That is, a light transmission area of an edge region of the optical path control member, which has a relatively small amount of light, is formed large. Therefore, the light transmittance of the edge region increases.

Accordingly, the difference in the light transmittance between the center region and the edge region of the optical path control member decreases. Therefore, the brightness uniformity of the optical path control member is improved.

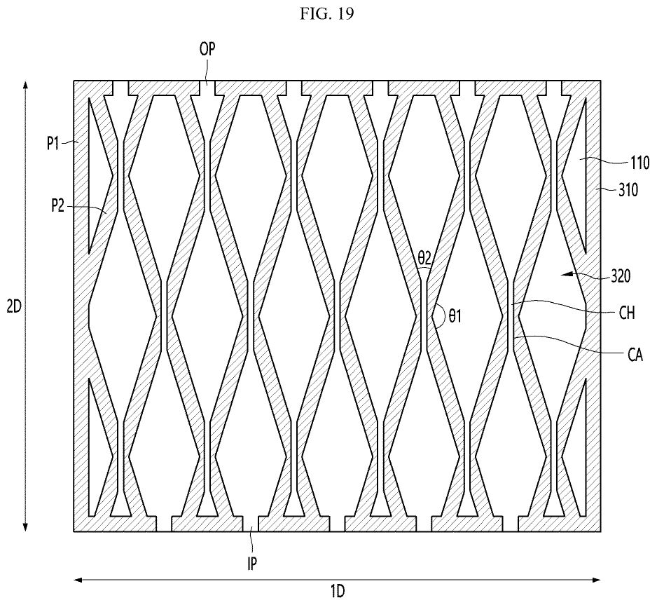

Referring to FIGS. 18 to 20, the partition wall part can be disposed in various shapes.

Referring to FIG. 18, the partition wall part 310 has an incline. Specifically, the second pattern part P2 is inclined with respect to the second direction 2D. Accordingly, the receiving part 320 is inclined with respect to the second direction 2D.

For example, the second pattern part P2 is inclined at an angle range set with respect to the second direction 2D. Specifically, the second pattern part P2 is tilted at an angle (θ) of 10° to 20° with respect to the second direction 2D.

Referring to FIG. 19, the partition wall part 310 includes intersecting pattern parts. Specifically, the second pattern parts P2 are disposed while intersecting each other. For example, the second pattern parts P2 may be disposed in a mesh shape.

In addition, a through hole CH is disposed in an intersection region CA of the second pattern part P2. Accordingly, when filling the light conversion material 330 inside the receiving part 320, the light conversion material 330 moves by the through hole CH.

In addition, an angle formed by the intersection region CA may be less than 90° or greater than 90°. For example, a first angle θ1 formed by the intersection region CA may be formed as an obtuse angle. In addition, a second angle θ2 formed by the intersection region CA may be formed as an acute angle. For example, a difference between the first angle θ1 and the second angle θ2 may be 10° to 20°.

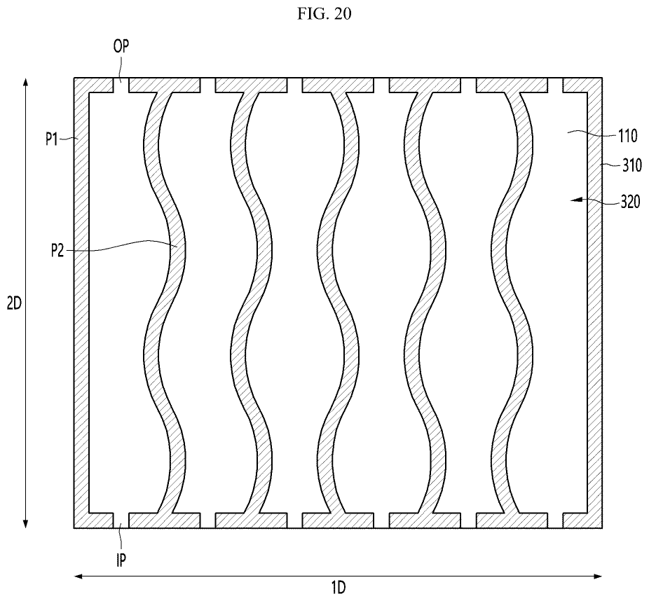

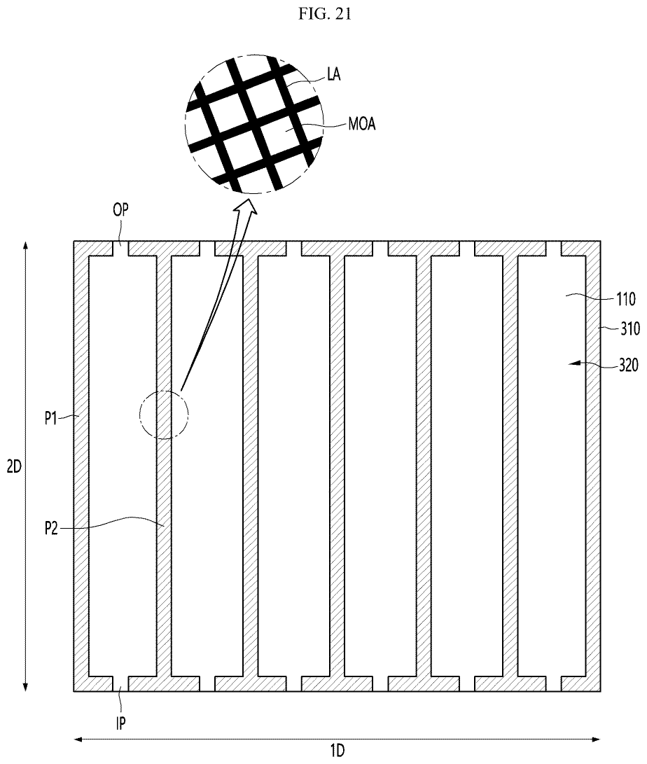

Referring to FIG. 20, the partition wall part 310 is disposed in a curved shape. In detail, the second pattern part P2 is disposed with a curvature. For example, the second pattern part P2 can extend in the second direction 2D with a curvature in various directions and various sizes.

In addition, at least one second pattern part P2 among the plurality of second pattern parts P2 can be disposed with a curvature of a different size and a different direction from at least other one second pattern part P2. That is, the second pattern part P2 is disposed in a random shape.

The optical path control member according to the embodiment arranges the partition wall part in various shapes. Accordingly, the user's visibility is improved.

In detail, as shown in FIG. 18, the second pattern part is tilted. Accordingly, when the optical path control member and the display panel are combined, the moire phenomenon due to the overlapping of the pixel pattern of the display panel the second pattern part is reduced. That is, the second pattern part is tilted at a set angle range. Accordingly, the user's visibility is improved.

In addition, as shown in FIG. 19, the second pattern part intersects. That is, the second pattern part is disposed in a mesh shape. Accordingly, when the optical path control member and the display panel are combined, the moire phenomenon due to the overlapping of the second pattern part and the pixel pattern of the display panel is reduced. That is, the second pattern part is disposed while intersecting at an angle within a set range. Accordingly, the user's visibility is improved.

In addition, as shown in FIG. 20, the second pattern part is disposed in a random shape or a curved shape. Accordingly, when the optical path control member and the display panel are combined, the moire phenomenon due to the overlapping of the second pattern part and the pixel pattern of the display panel is reduced. That is, the second pattern part is disposed in a random shape or a curved shape. Accordingly, the user's visibility is improved.

Referring to FIG. 21, the partition wall part 310 includes a mesh electrode. FIG. 21 illustrates that the second pattern part P2 is formed as a mesh electrode. However, the embodiment is not limited thereto. For example, at least one of the first pattern part P1 and the second pattern part P2 may be formed as a mesh electrode.

In detail, the partition wall part 310 may be formed as a mesh electrode including a mesh line LA and a mesh opening MOA. Accordingly, the transmittance of the optical path control member is improved. In detail, even if the partition wall part includes an opaque metal, light is transmitted through the mesh opening MOA. Accordingly, the light transmittance of the optical path control member is improved.

In addition, the user's visibility is improved. That is, the partition wall part is formed as a mesh electrode formed with a fine line width. Accordingly, the partition wall part is prevented from being recognized from the outside. Accordingly, the user's visibility is improved.

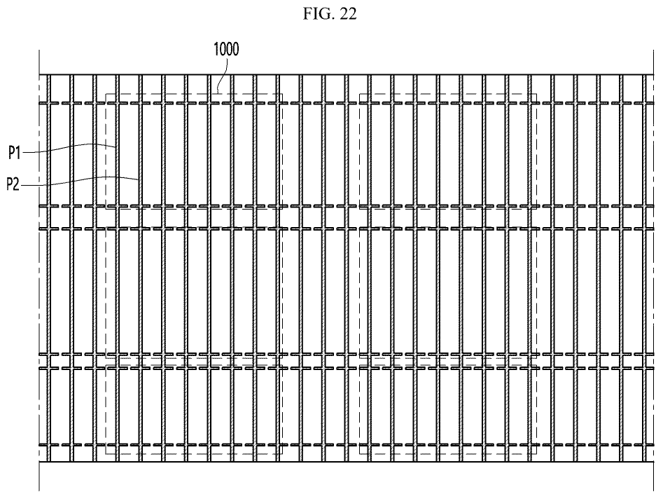

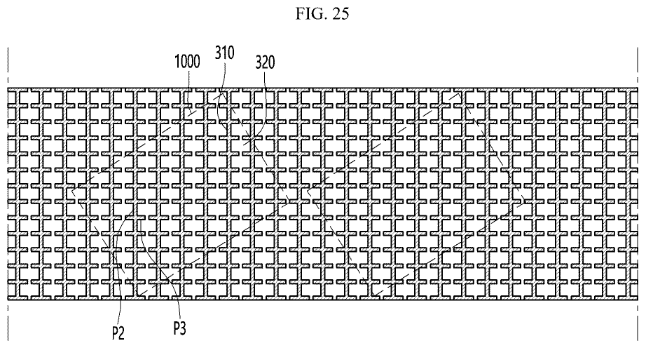

Referring to FIGS. 22 to 25, an injection part IP and an outlet part OP of the optical path control member 1000 are omitted.

In detail, a pattern part of a partition wall part is disposed on a large-area substrate. Then, an optical path control member having an area of a set range is individually cut.

For example, when the optical path control member 1000 is cut as in FIG. 22, the optical path control member 1000 includes a partition wall part having a stripe shape.

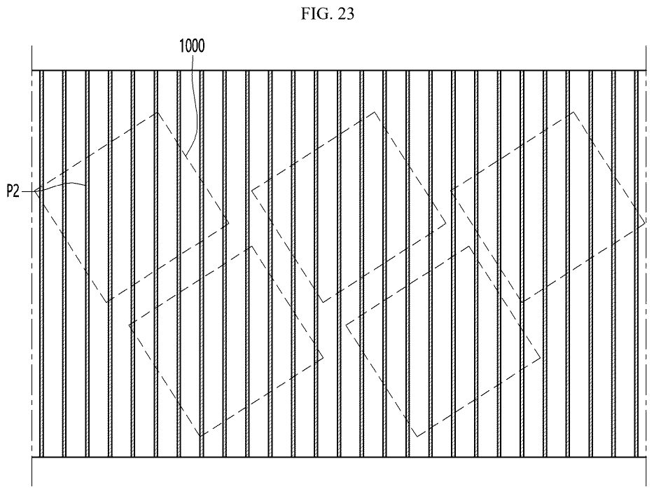

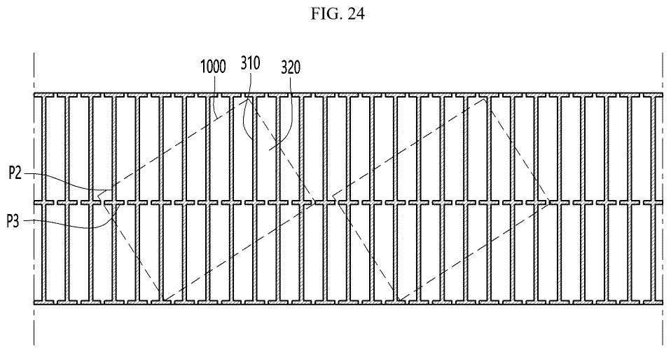

Alternatively, when the optical path control member 1000 is cut as in FIGS. 23 to 25, the optical path control member 1000 includes a partition wall part that is tilted with respect to the first direction and the second direction.

In addition, at least one pattern part among the first pattern part P1, the second pattern part P2, and the third pattern part P3 may be omitted.

That is, a pattern of a partition wall part is formed on one large-area substrate. Then, the optical path control member is formed by cutting it to a set area. Therefore, the optical path control member is easily manufactured. In addition, a process of forming a separate injection part and outlet part for each optical path control member is omitted.

Meanwhile, the partition wall part 310 of FIGS. 13 to 25 described above is disposed on the first substrate 110 with a certain area. In detail, an area of the partition wall part 310 may be less than 30%, less than 20%, less than 10%, less than 5%, or less than 3% of a total area of the first substrate 110. That is, an opening area where the partition wall part 310 is not disposed in the first substrate 110 may be 70% or more, 80% or more, 90% or more, 95% or more, or 97% or more.

If the area of the partition wall part 310 is 30% or more of the total area of the first substrate 110, the opening area through which light is transmitted decreases. Therefore, the brightness of the optical path control member decreases.

In addition, the light transmittance of the first mode may be 3% or less or 5% or less. The light transmittance of 3% or less means that when the amount of light incident on the optical path control member is defined as 100%, the amount of light emitted from an emission surface of the optical path control member is 3% or less. Alternatively, the light transmittance of the first mode may be less than an area ratio of the partition wall part. For example, when the area ratio of the partition wall part to the total area is 30%, the amount of light emitted from the emission surface of the optical path control member may be 30% or less.

In addition, the light transmittance of the second mode may be 70% or less. That is, the light transmittance of the second mode may be less than or equal to the open area. In detail, the light transmittance of the second mode may be 60% or less. In more detail, the light transmittance of the second mode may be 50% or less. In more detail, the light transmittance of the second mode may be 30% or less. In addition, the light transmittance of the second mode may be greater than or equal to the area ratio of the partition wall part to the total area.

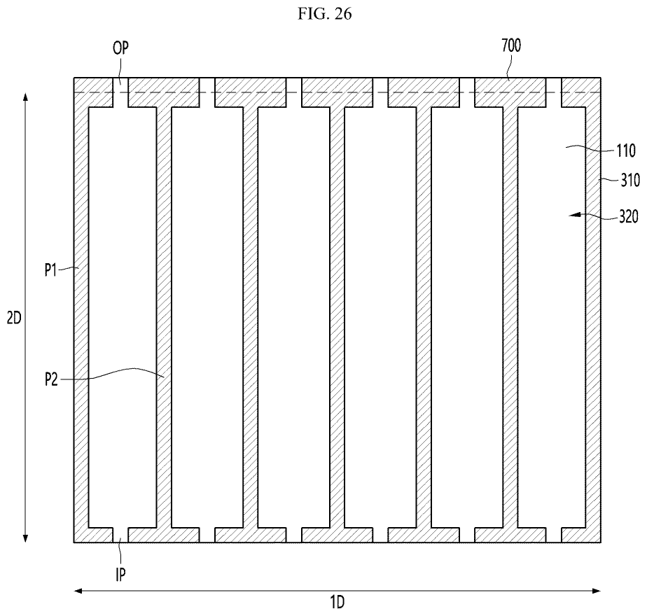

Hereinafter, a connection relationship between the partition wall part 310 and a printed circuit board according to the embodiment will be described with reference to FIGS. 26 to 28.

Referring to FIGS. 26 to 28, the partition wall part 310 according to the embodiment is connected to the printed circuit board. The partition wall part 310 is connected to a pad part 700 and/or a wiring electrode 800 connected to the printed circuit board.

Referring to FIG. 26, the partition wall part 310 is connected to the pad part 700. In detail, the pad part 700 is disposed at an edge of the first substrate 110. In addition, the pad part 700 is connected to the partition wall part 310.

A conductive adhesive layer is disposed on the pad part 700. The pad part of the printed circuit board and the pad part 700 are electrically connected by the conductive adhesive layer. The conductive adhesive layer may be an anisotropic conductive adhesive layer. Alternatively, the conductive adhesive layer is omitted. In detail, the pad part 700 and the pad part of the printed circuit board are in direct contact.

Accordingly, the partition wall part 310 and the printed circuit board are electrically connected.

The partition wall part 310 and the pad part 700 can be in direct contact. The partition wall part 310 and the pad part 700 can include the same material. The partition wall part 310 and the pad part 700 can be formed by the same process. For example, the partition wall part 310 and the pad part 700 can be formed integrally. For example, when forming the partition wall part 310, the width of one of the first pattern parts P1 disposed at the edge of the first substrate 110 can be formed large. Accordingly, one of the first pattern parts P1 can function as the pad part 700. However, the embodiment is not limited thereto. That is, the partition wall part 310 and the pad part 700 can include different materials. In addition, the partition wall part 310 and the pad part 700 may be formed by different processes.

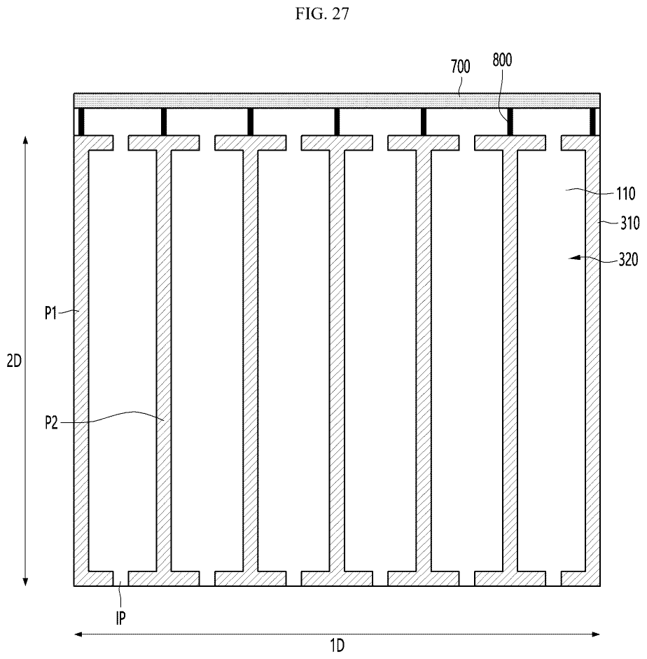

Referring to FIG. 27, the partition wall part 310 is connected to the wiring electrode 800 and the pad part 700. In detail, the wiring electrode 800 is connected to the partition wall part 310 and the pad part 700. Accordingly, the partition wall part 310 and the pad part 700 are electrically connected.

In detail, the pad part 700 is disposed at the edge of the first substrate 110. In addition, the pad part 700 is connected to the partition wall part 310.

A number of the wiring electrodes 800 may correspond to a number of the plurality of second pattern parts P2 that are spaced apart from each other. Accordingly, the wiring electrodes 800 are respectively connected to the plurality of second pattern parts P2.

The wiring electrode 800 can be connected to one pad part 700. That is, a plurality of wiring electrodes 800 are connected to the same pad part 700.

A conductive adhesive layer is disposed on the pad part 700. The pad part of the printed circuit board and the pad part 700 are electrically connected by the conductive adhesive layer. Alternatively, the conductive adhesive layer is omitted. In detail, the pad part 700 and the pad part of the printed circuit board are in direct contact.

Accordingly, the partition wall part 310 and the printed circuit board are electrically connected.

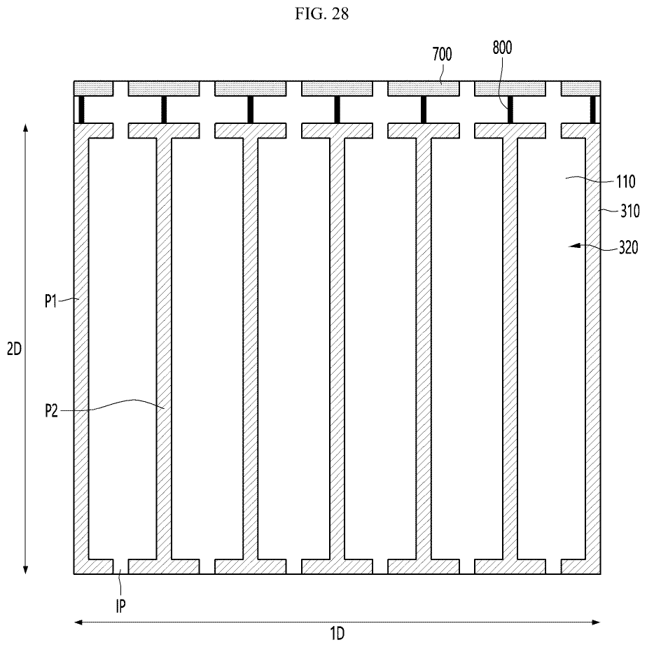

Referring to FIG. 28, the partition wall part 310 is connected to the wiring electrode 800 and the pad part 700. In detail, the wiring electrode 800 is connected to the partition wall part 310 and the pad part 700. As a result, the partition wall part 310 and the pad part 700 are electrically connected.

In detail, the pad part 700 is disposed at the edge of the first substrate 110. In addition, the pad part 700 is connected to the partition wall part 310.

The number of the wiring electrodes 800 may correspond to the number of the plurality of second pattern parts P2 that are spaced apart from each other. Accordingly, the wiring electrodes 800 are respectively connected to the plurality of second pattern parts P2.

In addition, the number of the pad parts 700 may correspond to the number of the plurality of wiring electrodes 800 that are spaced apart from each other. Accordingly, the pad part 700 is respectively connected to the plurality of wiring electrodes 800.

That is, the second pattern part P2, the wiring electrodes 800 and the pad part 700 are disposed in the same number.

A conductive adhesive layer is disposed on the pad part 700. The pad part of the printed circuit board and the pad part 700 are electrically connected by the conductive adhesive layer. Alternatively, the conductive adhesive layer may be omitted. That is, the pad part 700 and the pad part of the printed circuit board are in direct contact.

Accordingly, the partition wall part 310 and the printed circuit board are electrically connected.

Each of the second pattern parts P2 may be connected to another wiring electrode 800 and another pad part 700. Accordingly, voltage is individually applied to a plurality of second pattern parts P2. That is, when a power of the optical path control member 1000 is turned on, voltage may be applied to at least one second pattern part P2. In addition, voltage may not be applied to at least one other second pattern part P2.

Accordingly, light conversion particles move in at least one receiving part 320. Additionally, light conversion particles do not move in at least another receiving part 320.

Accordingly, the optical path control member is driven by a local dimming. That is, light is blocked in one region of the optical path control member, and light is transmitted in another region. Accordingly, the optical path control member is driven in various modes according to the user's needs.

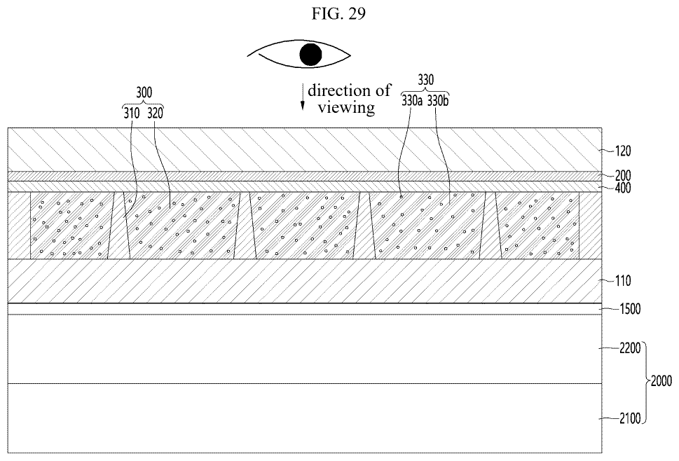

Hereinafter, referring to FIGS. 29 to 35, a display device and a display device to which an optical path control member according to an embodiment is applied will be described.

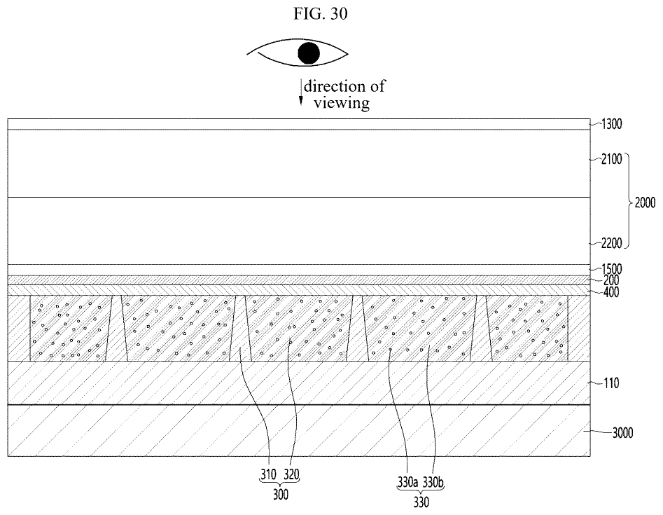

Referring to FIGS. 29 and 30, an optical path control member 1000 according to an embodiment may be disposed on or below a display panel 2000.

The display panel 2000 and the optical path control member 1000 may be disposed while being adhered to each other. For example, the display panel 2000 and the optical path control member 1000 may be adhered to each other through an adhesive member 1500. The adhesive member 1500 may be transparent. For example, the adhesive member 1500 may include an adhesive or an adhesive layer including an optically transparent adhesive material.

The adhesive member 1500 may include a release film. In detail, when bonding the optical path member and the display panel, the optical path control member and the display panel can be bonded after removing the release film.

The display panel 2000 may include a first base substrate 2100 and a second base substrate 2200. The display panel 2000 may be formed with a structure in which a first base substrate 2100 including a thin film transistor (TFT) and a pixel electrode and a second base substrate 2200 including color filter layers are bonded with a liquid crystal layer interposed therebetween.

In addition, the display panel 2000 may be a liquid crystal display panel having a COT (color filter on transistor) structure in which a thin film transistor, a color filter, and a black electrolyte are formed on the first base substrate 2100, and the second base substrate 2200 is bonded with the first base substrate 2100 with a liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this time, in order to improve an open ratio and simplify a mask process, the black electrolyte may be omitted, and a common electrode may be formed to also serve as the black electrolyte.

As shown in FIG. 29, when the display panel 2000 is an organic light-emitting display panel, the optical path control member may be formed on an upper portion of the organic light-emitting display panel. That is, when a surface of the organic light-emitting display panel that the user views is defined as the upper portion of the organic light-emitting display panel, the optical path control member may be disposed on the upper portion of the organic light-emitting display panel. The display panel 2000 may include a self-luminous element that does not require a separate light source. The display panel 2000 may have a thin film transistor formed on a first base substrate 2100, and an organic light-emitting element formed in contact with the thin film transistor. The organic light-emitting element may include an anode, a cathode, and an organic light-emitting layer formed between the anode and the cathode. In addition, the display panel may further include a second base substrate 2200 that serves as a sealing substrate for encapsulation on the organic light-emitting element.

Alternatively, when the display panel 2000 is a liquid crystal display panel, the optical path control member may be formed on the upper portion of the liquid crystal panel. That is, when the surface of the liquid crystal panel that the user views is defined as the upper portion of the liquid crystal panel, the optical path control member may be disposed on the upper portion of the liquid crystal panel. That is, as shown in FIG. 30, the optical path control member is disposed below the liquid crystal panel and above the backlight unit 3000, so that the optical path control member can be disposed between the backlight unit 3000 and the display panel 2000.

In addition, although not shown in the drawing, a polarizing plate may be further disposed between the optical path control member 1000 and the display panel 2000. The polarizing plate may be a linear polarizing plate or an anti-reflection polarizing plate. For example, when the display panel 2000 is a liquid crystal display panel, the polarizing plate may be a linear polarizing plate. In addition, when the display panel 2000 is an organic light-emitting diode panel, the polarizing plate may be an anti-reflection polarizing plate.

In addition, an additional functional layer 1300, such as an anti-reflection layer or an anti-glare layer, may be further disposed on the optical path control member 1000. In detail, the functional layer 1300 may be bonded to one side of the first substrate 110 of the optical path control member. Although not shown in the drawing, the functional layer 1300 may be bonded to the second substrate 120 of the optical path control member through an adhesive layer. In addition, a release film protecting the functional layer may be further disposed on the functional layer 1300.

In addition, a touch panel may be further disposed between the display panel and the optical path control member.

In the drawing, the optical path control member is depicted as being disposed at an upper side of the display panel, but the embodiment is not limited thereto, and the optical path control member may be disposed at various locations where light control is possible, such as at a lower side of the display panel or between the second substrate and the first substrate of the display panel.

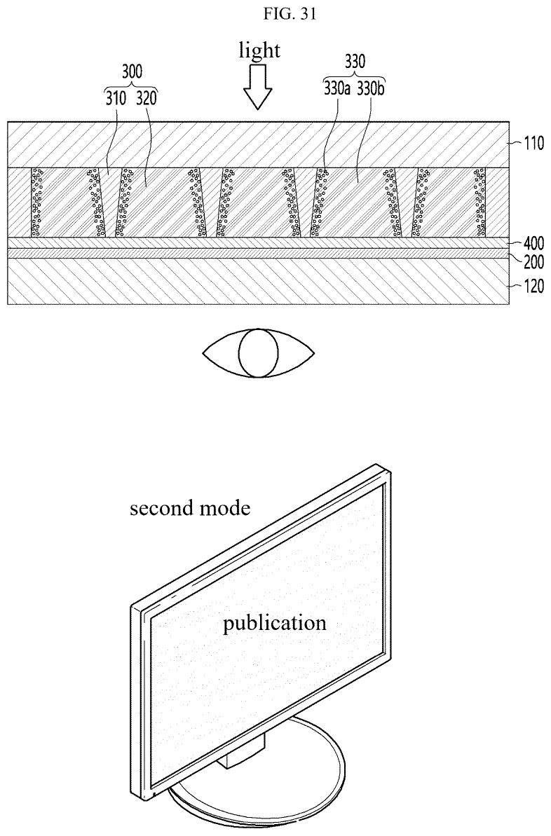

Referring to FIGS. 31 to 35, the optical path control member according to the embodiment may be applied to various display devices.

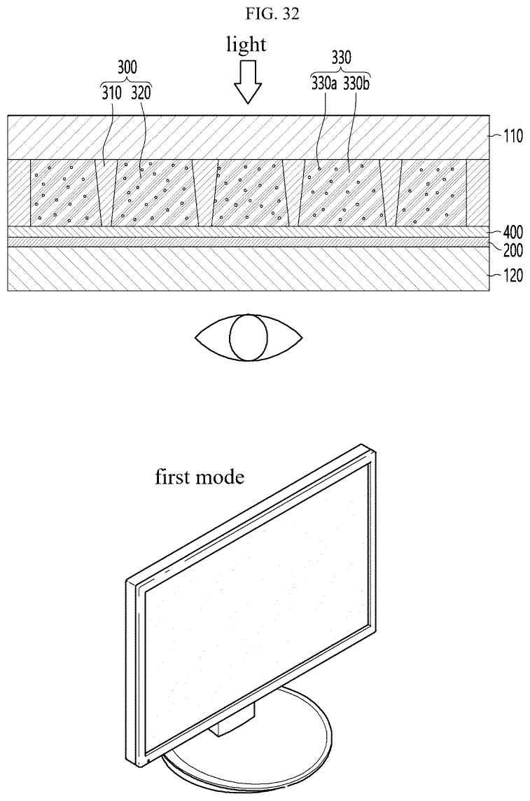

Referring to FIGS. 31 and 32, the optical path control member according to the embodiment can be applied to a display device that displays a screen.

For example, when power is applied to the optical path control member as in FIG. 31, the receiving part becomes a light transmitting part. Accordingly, the display device is driven in the second mode. In addition, when power is not applied to the optical path control member as in FIG. 32, the receiving part becomes a light blocking part. Accordingly, the display device is driven in the first mode.

Accordingly, the user can use the display device in a privacy mode or a light blocking mode depending on the application of power.

The light emitted from the backlight unit or the self-luminous element can move from the first substrate toward the second substrate. Alternatively, the light emitted from the backlight unit or the self-luminous element can also move from the first substrate toward the second substrate.

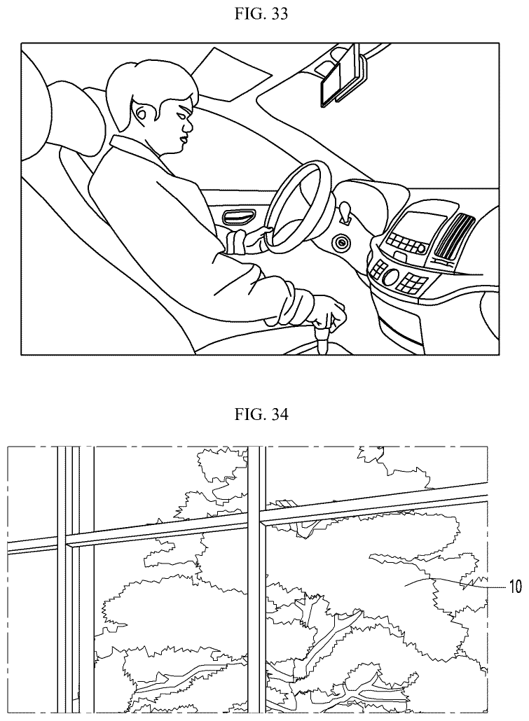

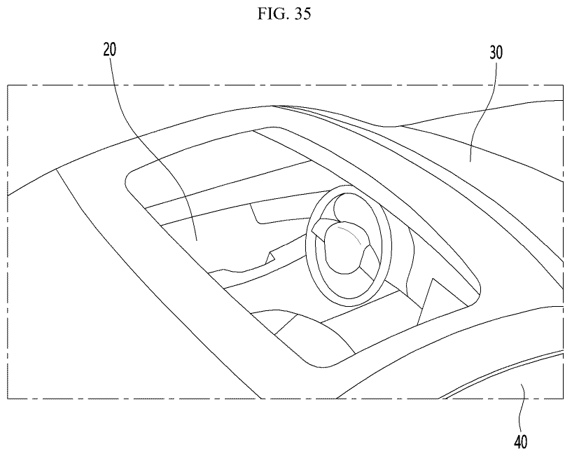

In addition, referring to FIGS. 33 and 35, the display device to which the optical path control member according to the embodiment is applied can be applied to an interior and exterior of a vehicle and windows of a building.

For example, a display device including an optical path control member according to an embodiment as in FIG. 33 can display information about a vehicle and an image for confirming a vehicle's moving path. The display device can be placed between a driver's seat and a passenger seat of the vehicle.

In addition, the optical path control member according to the embodiment can be applied to a dashboard that displays the speed, engine, and warning signals of the vehicle.

In addition, as shown in FIG. 34, the optical path control member according to the embodiment can be applied to a window 10 of a building. Accordingly, the amount of light passing through the window 10 can be controlled.

In addition, as shown in FIG. 35, the optical path control member according to the embodiment can be applied to a sunroof 20, a windshield 30, or left and right windows 40 of the vehicle.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An optical path control member comprising:
a first substrate;
a light conversion unit disposed on the first substrate;
a second substrate disposed on the light conversion unit; and
a second electrode disposed between the second substrate and the light conversion unit,
wherein the light conversion unit includes a partition wall part and a receiving part which that are alternately disposed,
wherein the partition wall part includes a first electrode,
wherein a light conversion material is disposed inside the receiving part, and
wherein a width of the partition wall part is smaller than a width of the receiving part.

2. The optical path control member of claim 1, wherein the light conversion unit is in direct contact with the first substrate.

3. The optical path control member of claim 1, wherein the light conversion material includes a dispersion liquid and light conversion particles dispersed in the dispersion liquid, and
wherein when a voltage is applied to the first electrode and the second electrode, the light conversion particles move in a direction toward a side surface of the partition wall part.

4. The optical path control member of claim 1, wherein the partition wall part includes at least one layer.

5. The optical path control member of claim 4, wherein the first electrode of the partition wall part includes a first metal layer and a second metal layer on the first metal layer, and
wherein the first metal layer and the second metal layer include different metals.

6. The optical path control member of claim 1, wherein a thickness of the partition wall part is 5 μm to 100 μm.

7. The optical path control member of claim 6, wherein the partition wall part has a ratio (T/W1) of a thickness (T) of the partition wall part to a width W1 of the partition wall part of 1 to 10.

8. The optical path control member of claim 1, wherein the partition wall part includes an insulating layer disposed on at least one of an upper surface, a lower surface, or a side surface of the first electrode of the partition wall part.

9. The optical path control member of claim 8, wherein a surface roughness of the insulating layer is greater than a surface roughness of the first electrode.

10. The optical path control member of claim 1, wherein the partition wall part includes a first pattern part disposed at an edge of the first substrate and a plurality of second pattern parts disposed inside the first pattern part, and
wherein the plurality of second pattern parts are disposed spaced apart from each other.

11. The optical path control member of claim 10, comprising:
a third pattern part connected to the first pattern part or the second pattern part.

12. The optical path control member of claim 11, wherein the receiving part includes at least one open region formed by the third pattern part.

13. The optical path control member of claim 12, wherein a width of the open region is 0.5 to 5 times a width of the second pattern part.

14. The optical path control member of claim 12, wherein the open region is alternately disposed inside the receiving part.

15. The optical path control member of claim 1, wherein the receiving part includes a region whose width changes while extending in one direction.

16. The optical path control member of claim 1, wherein the partition wall part is disposed in an area of less than 30% of a total area of the first substrate.

17. The optical path control member of claim 1, wherein the optical conversion unit is driven in a first mode when no voltage is applied to the first electrode and the second electrode in an off state,
wherein the optical conversion unit is driven in a second mode when voltage is applied to the first electrode and the second electrode,
wherein a light transmittance of the first mode is 3% or less, and
wherein a light transmittance of the second mode is 70% or less.

18. A display device comprising:
a panel including a display panel or a touch panel; and an optical path control member disposed on or under the panel,
wherein the optical path control member comprises:
a first substrate;
a light conversion unit disposed on the first substrate;
a second substrate disposed on the light conversion unit; and
a second electrode disposed between the second substrate and the light conversion unit,
wherein the light conversion unit includes a partition wall part and a receiving part that are alternately disposed,
wherein the partition wall part includes a first electrode,
wherein a light conversion material is disposed inside the receiving part,
wherein a width of the partition wall part is smaller than a width of the receiving part, and
wherein the light conversion unit is in direct contact with the first substrate.

19. The display device of claim 18, wherein the panel includes a backlight unit and a liquid crystal display panel, and
wherein the optical path control member is disposed between the backlight unit and the liquid crystal display panel, and
wherein when light is emitted from the backlight unit the light moves from the first substrate toward the second substrate.

20. The display device of claim 18, wherein the panel includes an organic light emitting diode panel,
wherein the optical path control member is disposed on the organic light emitting diode panel, and
wherein when light is emitted from the panel the light moves from the first substrate toward the second substrate.
